(19) United States
(12) Patent Application Publication
(10) Pub. No.: US 2014/0314539 A1
(43) Pub. Date: Oct. 23, 2014

(54) NON-CONTACT SUBSTRATE TRANSFER TURNER

(71) Applicant: Samsung Electro-Mechanics Co., Ltd., Suwon (KR)

(72) Inventors: Yong Kwan LEE, Suwon (KR); Sun KIM, Suwon (KR); Hyun Su KIM, Suwon (KR)

(73) Assignee: Samsung Electro-Mechanics Co., Ltd., Suwon (KR)

(21) Appl. No.: 14/049,778

(22) Filed: Oct. 9, 2013

(30) Foreign Application Priority Data
Apr. 17, 2013 (KR) 10-2013-0042382

(51) Int. Cl. H01L 21/68

(52) U.S. Cl. CPC H01L 21/68
USPC 414/758

(57) ABSTRACT

Disclosed herein is a non-contact substrate transfer turner capable of performing a transfer and a turn-over of a substrate in a non-contact state. The non-contact substrate transfer turner includes a transfer member moving along a guide rail; a substrate supporting member installed at the transfer member and non-contact supporting a substrate by drag force and lift force; and a power transmitting member providing power to the substrate supporting member to rotate the substrate supporting member.

### CROSS REFERENCE(S) TO RELATED APPLICATIONS

This application claims the benefit under 35 U.S.C. Section 119 of Korean Patent Application Serial No. 10-2013-0042382, entitled “Non-Contact Substrate Transfer Turner” filed on Apr. 17, 2013, which is hereby incorporated by reference in its entirety into this application.

### BACKGROUND OF THE INVENTION

1. Technical Field

The present invention relates to a non-contact substrate transfer turner, and more particularly, to a non-contact substrate transfer tuner capable of progressing a transfer and a turn-over of a substrate in a non-contact state.

2. Description of the Related Art

Generally, an exposing apparatus mainly used in a process of manufacturing a substrate or a semiconductor is used for implementing of a fine circuit pattern, curing a solder resist, or the like.

During the process of using the exposing apparatus, since a circuit line width of substrates have becomes recently smaller and a demand of a multi-layer substrate has increased, a circuit defect is frequently generated due to optical characteristics disturbance caused by foreign materials during a manufacturing process.

This problem is generated because the substrate is transferred and turned-over in a state in which it directly contacts an apparatus such as a transfer table.

That is, the defect caused by the foreign materials means that the foreign materials are absorbed on a surface of the substrate by friction between a product and a transfer conveyor, a transfer roller, or the like at the time of transferring the substrate.

Particularly, since the multi-layer substrate having an increased laminating layer number of substrates repeatedly performs several processes, it is seriously subjected to contamination caused by the foreign materials and this contamination eventually causes a fatal problem in qualitatively improving the product.

### RELATED ART DOCUMENT

### Patent Document

(Patent Document 1) Japanese Patent Laid-open Publication No. 2008-147291

### SUMMARY OF THE INVENTION

An object of the present invention is to provide a non-contact substrate transfer turner capable of minimizing optical characteristics disturbance caused by foreign materials by enabling a transfer and a turn-over of a substrate to be performed in a state in which the substrate does not contact a transfer table.

In addition, another object of the present invention is to provide a non-contact substrate transfer turner capable of anticipating an increase of productivity by enabling the transfer and the turn-over of the substrate to be rapidly performed.

According to an exemplary embodiment of the present invention, there is provided a non-contact substrate transfer turner, including: a transfer member moving along a guide rail; a substrate supporting member installed at the transfer member and non-contact supporting a substrate by drag force and lift force; and a power transmitting member providing power to the substrate supporting member to rotate the substrate supporting member.

The guide rail may be provided with a limit switch limiting a movement distance of the transfer member.

The substrate supporting member may include a frame, an air sucking part installed at the frame and sucking foreign materials absorbed on a substrate, and an air discharging part installed at the frame and supporting the substrate in a non-contact state by air discharge.

The air sucking part and the air discharging part may be alternately installed, respectively and the air discharging part may include an air discharging hole formed to be inclined at a predetermined angle.

A pair of substrate supporting members may be provided at an upper side of the transfer member and the substrate supporting members may be rotated in a clockwise direction and a counterclockwise direction, respectively.

The pair of substrate supporting members may be configured of a turn-over supplying part non-contact transferring the substrate and a turn-over receiving part receiving the substrate supplied through the turn-over supplying part.

The power transmitting member may include a motor providing power so as to ascend and descend the substrate supporting member according to a rotational direction, a decelerator decelerating the number of revolutions of the motor, and a rotational rotary motor rotating the substrate supporting member.

The transfer member may be configured by using any one of a linear motor, a screw, a belt, and a chain.

### BRIEF DESCRIPTION OF THE DRAWINGS

FIG. 1 is a perspective view showing a non-contact substrate transfer turner according to an exemplary embodiment of the present invention;

FIG. 2 is a plan view of the non-contact substrate transfer turner according to the exemplary embodiment of the present invention;

FIG. 3 is a side view of the non-contact substrate transfer turner according to the exemplary embodiment of the present invention;

FIG. 4 is a side view of the non-contact substrate transfer turner according to the exemplary embodiment of the present invention;

FIG. 5 is a perspective view showing only a non-contact transfer module of components of the non-contact substrate transfer turner according to the exemplary embodiment of the present invention;

FIG. 6 is an exploded perspective view showing a substrate transfer member of the non-contact substrate transfer turner according to the exemplary embodiment of the present invention;

FIG. 7 is a cross-sectional view of the substrate transfer member of the non-contact substrate transfer turner according to the exemplary embodiment of the present invention;

FIG. 8 is a side view showing a process in which a substrate is turned-over by the non-contact substrate transfer turner according to the exemplary embodiment of the present invention; and

FIG. 9 is a perspective view showing a state in which the substrate is turned-over by the non-contact substrate transfer turner according to the exemplary embodiment of the present invention.

### DESCRIPTION OF THE PREFERRED EMBODIMENTS

Hereinafter, exemplary embodiments of the present invention will be described in detail with reference to the accompanying drawings.

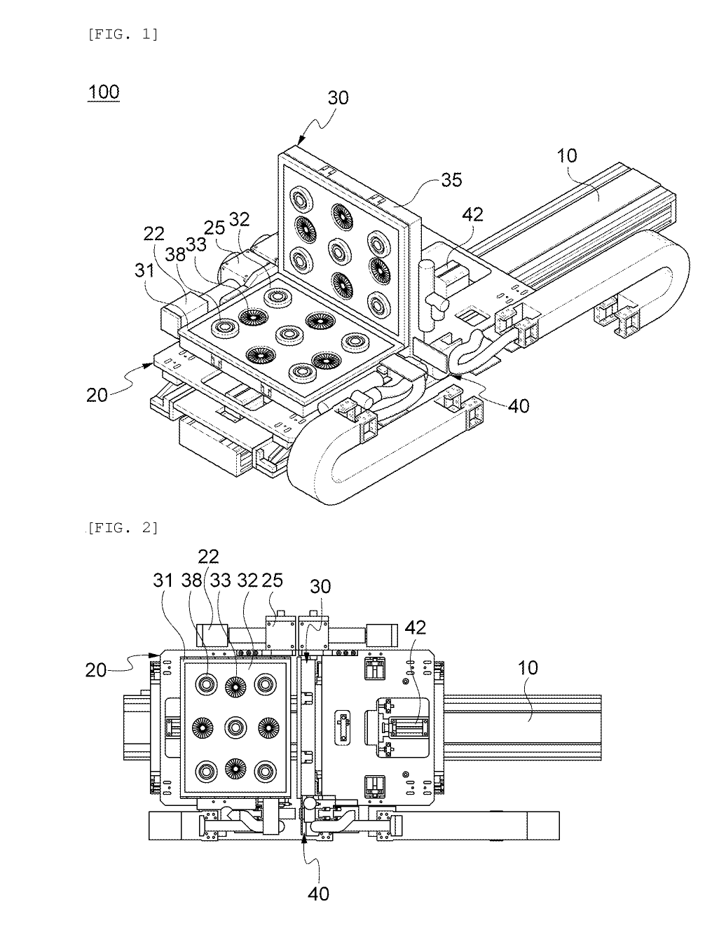

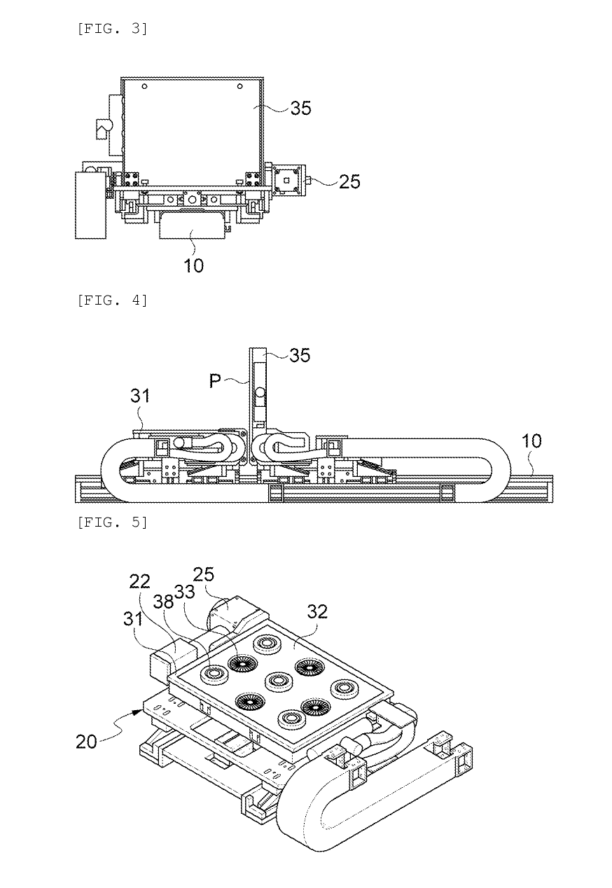

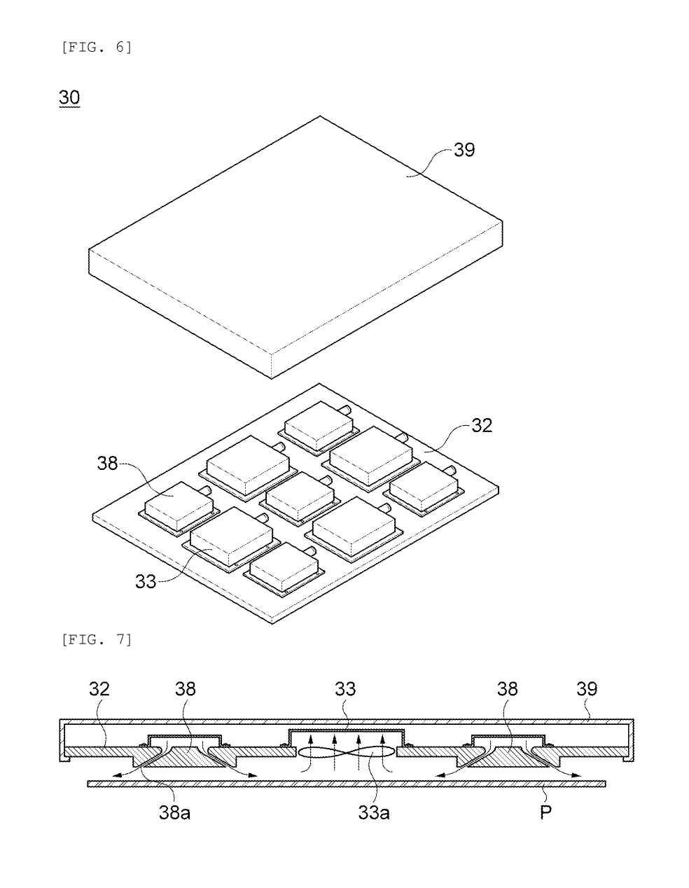

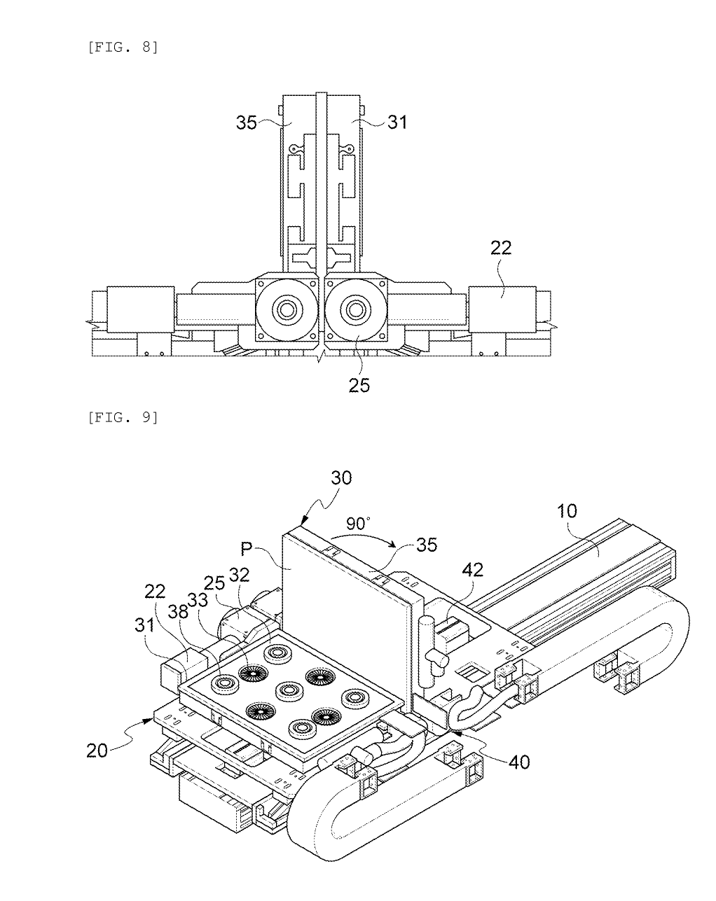

FIG. 1 is a perspective view showing a non-contact substrate transfer turner according to an exemplary embodiment of the present invention, FIG. 2 is a plan view of the non-contact substrate transfer turner according to the exemplary embodiment of the present invention, FIG. 3 is a side view of the non-contact substrate transfer turner according to the exemplary embodiment of the present invention, FIG. 4 is a side view of the non-contact substrate transfer turner according to the exemplary embodiment of the present invention, FIG. 5 is a perspective view showing only a non-contact transfer module of components of the non-contact substrate transfer turner according to the exemplary embodiment of the present invention, FIG. 6 is an exploded perspective view showing a substrate transfer member of the non-contact substrate transfer turner according to the exemplary embodiment of the present invention, FIG. 7 is a cross-sectional view of the substrate transfer member of the non-contact substrate transfer turner according to the exemplary embodiment of the present invention, FIG. 8 is a side view showing a process in which a substrate is turned-over by the non-contact substrate transfer turner according to the exemplary embodiment of the present invention, and FIG. 9 is a perspective view showing a state in which the substrate is turned-over by the non-contact substrate transfer turner according to the exemplary embodiment of the present invention.

As shown in FIGS. 1 to 5, a non-contact substrate transfer turner 100 according to an exemplary embodiment of the present invention is configured to minimize contamination caused by foreign materials and to rapidly supply a substrate by transferring and turning-over the substrate in a non-contact state.

In the non-contact substrate transfer turner 100 according to the exemplary embodiment of the present invention, a linear motor 10 is disposed to transfer the substrate and a transfer member 20 moves along a guide rail (not shown) installed in the linear motor 10, such that the substrate is supplied to a next process.

One or more guide rails may be disposed according to a design specification of the turner 100. In this case, the guide rail may be installed with a limit switch (not shown) in order to limit a movement distance of the transfer member 20, where the limit switch may be installed at the transfer member 20 rather than the guide rail.

The transfer member 20 receives power through any one of the linear motor, a screw, a belt, a chain, and the like at the time of moving along the guide rail.

Among these, since the linear motor 10 is most widely used in an apparatus moving along the guide rail, the present invention also shows a case in which the linear motor 10 is used.

The transfer member 20 has a substrate supporting member 30 installed at an upper side thereof so that the substrate may be transferred and turned-over in a non-contact state.

A pair of substrate supporting members 30 may be configured at an upper portion of the transfer member in a rotatable state. The substrate supporting member 30 includes a turn-over supplying part 31 and a turn-over receiving part 35 receiving the substrate supplied through the turn-over supplying part 31 in order to maintain the non-contact state in a process of transferring the substrate.

That is, the substrate supporting member 30 is configured of the turn-over supplying part 31 and the turn-over receiving part 35, where the turn-over supplying part 31 and the turn-over receiving part 35 may have the same structure according to a position at which they are installed at the transfer member 20.

The substrate supporting member 30 is configured to maintain a state in which the substrate does not contact, using drag force and lift force by air at the time of transferring and turning-over the substrate.

The above-mentioned substrate supporting member 30 includes a frame 32, an air sucking part 33 installed at the frame 32 and sucking foreign materials absorbed on a substrate P through an air sucking fan 33a, an air discharging part 38 installed at the frame 32 and supporting the substrate P in the non-contact state by air discharge, and a case 39 accommodating them therein.

The air sucking fan 33a and the air discharging part 38 may be alternately installed at the frame 32.

In addition, the air discharging part 38 discharges the air at an slant toward the substrate P to provide the lift force and the drag force, thereby making the substrate P in the non-contact state, and the air sucking fan 33a may remove the foreign materials on the surface of the substrate P by sucking the air from the substrate P.

In this case, the air discharging part 38 has an air discharging hole 38a having a shape inclined at a predetermined angle rather than a vertical direction so that the lift force is generated toward the surface of the substrate P.

In a case of the air discharging part 38, when the air discharging hole 38a is configured to be inclined at a predetermined angle and a flow speed of the air passing through the air discharging hole 38a is increased, the drag force and the lift force are simultaneously generated between the substrate P and the air discharging part 38.

The drag force and the lift force generated as described above may support the substrate P in the non-contact state by balancing with the sucking force sucking the substrate P through the air sucking fan 33a.

A principle capable of supporting the substrate P in the non-contact state as describe above is possible because Beroulli's theorem has been applied to the substrate supporting member.

That is, when the air is sprayed at high speed, an upper space of the substrate P has a low air pressure and a lower space of the substrate has a relatively high air pressure, such that a pressure difference between an upper portion and a lower portion based on the substrate P is generated and an upward lift force is generated as much as the generated pressure difference.

The lift force generated as described above floats the substrate P so that the substrate P does not closely adhere to the frame 32.

In addition, the air discharged from the air discharging part is discharged through the air discharging hole 38a formed approximately in a diagonal direction with respect to the substrate P. In this process, the drag force is generated by a sum of friction force and the lift force of the air flowing along the surface of the substrate P.

Therefore, the substrate P may maintain a state in which the substrate P does not contact the frame 32 by a balance with the drag force and the lift force generated through the air discharging part 38 and the sucking force generated through the air sucking fan 33a.

In addition, the substrate supporting member 30 may be rotated by 180° in a clockwise direction and a counterclockwise direction, respectively after being installed at an upper side of the transfer member 20, but the exemplary embodiment of the present invention shows the rotation at 90°.

For example, the turn-over supplying part 31 may be rotated 90° in the clockwise direction, and on the other hand, the turn-over receiving part 35 may be rotated 90° in the counterclockwise direction.

The rotational angle of the substrate supporting member 30 is formed when power is provided from a power transmitting member 40. The power transmitting member 40 may include a motor 42 providing power so as to ascend and descend the substrate supporting member 30 according to a rotational direction, a decelerator 25 decelerating the number of revolutions of the motor 42, and a rotational rotary motor 22 rotating the substrate supporting member 30 in any rotational angle range.

That is, when rotational force is generated by the motor 22, the decelerator 25 adjusts the number of revolutions of the motor 22 and provides the adjusted rotational force to the rotational rotary motor 22, such that the angle of the substrate supporting member 30 may be adjusted in any rotational angle range.

Here, in a case of the power transmitting member 40, the motor, the decelerator, and the rotational rotary motor 22 are described as the exemplary embodiment, but any form of configurations allowing a position of the substrate supporting member 30 to be rotated in a range of 90° or in any set angle may also be applied and used as the power transmitting member 40.

Hereinafter, a process of operating the non-contact substrate transfer turner according to the exemplary embodiment of the present invention will be described.

Referring to FIGS. 8 and 9, when the substrate P moves to an upper side of the turn-over supplying part 31 in order to perform a curing of a fine circuit pattern or a solder resist on the surface of the substrate P, the air sucking fan 33a and the air discharging part 38 suck and spray the air so that the substrate P does not directly adhere to the frame 32, thereby simultaneously generating the drag force and the lift force.

In the case in which the substrate P is supported at the upper side of the frame 32 by the air sucking fan 33a and the air discharging part 38, the transfer member 20 moves along the guide rail.

When the movement of the transfer member 20 is completed, the turn-over supplying part 31 is rotated 90° by an operation of the rotational rotary motor 22 and the decelerator 25 so as to become a vertical state.

At the same time, the turn-over receiving part 35 is also rotated 90° by the operation of the rotational rotary motor 22 and the decelerator 25 so as to become the vertical state.

Therefore, the turn-over supplying part 31 and the turn-over receiving part 35 facing each other in the vertical state simultaneously support the substrate P, such that the substrate P does not vertically fall and maintains a hold state.

In this case, the turn-over supplying part 31 and the turn-over receiving part 35 maintain a state in which they simultaneously supply the air, and when the air from the turn-over supplying part 31 is blocked, the substrate P is transferred to the turn-over receiving part 35 in the non-contact state.

Next, the turn-over supplying part 31 is returned to an original position by the operation of the rotary motor 22 and the decelerator 25.

In the case in which the turn-over supplying part 31 is returned to the original position, the turn-over receiving part 35 is also returned to the original position and continues to support the substrate P in the non-contact state at the returned position.

In this case, although not shown in drawings, the substrate P supported by the turn-over receiving part 35 in the non-contact state is transferred after a robot continues to receive the substrate in the non-contact state in order to proceed to a next process.

Therefore, the non-contact substrate transfer turner 100 according to the exemplary embodiment of the present invention may maintain the transfer of the substrate P in the non-contact state, may turn-over the position of the substrate P by the turn-over supplying part 31 and the turn-over receiving part 35, and may maintain the substrate P in the non-contact state in the turn-over process, thereby making it possible to minimize the contamination caused by the foreign materials.

Hereinabove, although the non-contact substrate transfer turner according to the exemplary embodiment of the present invention has been described, the present invention is not limited thereto, but may be variously modified and altered by those skilled in the art.

According to the exemplary embodiment of the present invention, the non-contact substrate transfer turner may minimize optical characteristics disturbance caused by the foreign materials by enabling the transfer and the turn-over of the substrate to be performed in a state in which the substrate does not contact the transfer table, such that an improvement of product characteristics may be anticipated.

In addition, the non-contact substrate transfer turner according to the exemplary embodiment of the present invention may rapidly perform the transfer and the turn-over of the substrate, such that the increase of productivity may be anticipated.

What is claimed is:

1. A non-contact substrate transfer turner, comprising:
a transfer member moving along a guide rail;
a substrate supporting member installed at the transfer member and non-contact supporting a substrate by drag force and lift force; and
a power transmitting member providing power to the substrate supporting member to rotate the substrate supporting member.

2. The non-contact substrate transfer turner according to claim 1, wherein the guide rail is provided with a limit switch limiting a movement distance of the transfer member.

3. The non-contact substrate transfer turner according to claim 1, wherein the substrate supporting member includes a frame, an air sucking part installed at the frame and sucking foreign materials absorbed on a substrate, and an air discharging part installed at the frame and supporting the substrate in a non-contact state by air discharge.

4. The non-contact substrate transfer turner according to claim 3, wherein the air sucking part and the air discharging part are alternately installed, respectively.

5. The non-contact substrate transfer turner according to claim 3, wherein the air discharging part includes an air discharging hole formed to be inclined at a predetermined angle.

6. The non-contact substrate transfer turner according to claim 1, wherein a pair of substrate supporting members is provided at an upper side of the transfer member and the substrate supporting members are rotated in a clockwise direction and a counterclockwise direction, respectively.

7. The non-contact substrate transfer turner according to claim 6, wherein the pair of substrate supporting members is configured of a turn-over supplying part non-contact transferring the substrate and a turn-over receiving part receiving the substrate supplied through the turn-over supplying part.

8. The non-contact substrate transfer turner according to claim 1 or 6, wherein the power transmitting member includes a motor providing power so as to ascend and descend the substrate supporting member according to a rotational direction, a decelerator decelerating the number of revolutions of the motor, and a rotational rotary motor rotating the substrate supporting member.

9. The non-contact substrate transfer turner according to claim 1, wherein the transfer member is configured by using any one of a linear motor, a screw, a belt, and a chain.
